(19) United States
(12) Patent Application Publication
(10) Pub. No.: US 2026/0243815 A1
(43) Pub. Date: Aug. 20, 2026

(54) SEMICONDUCTOR DEVICE

(71) Applicant: FUJI ELECTRIC CO., LTD., Kawasaki-shi (JP)

(72) Inventor: Takahiro SEKO, Suzuka-city (JP)

(73) Assignee: FUJI ELECTRIC CO., LTD., Kawasaki-shi (JP)

(21) Appl. No.: 19/437,679

(22) Filed: Dec. 31, 2025

(30) Foreign Application Priority Data
Feb. 14, 2025 (JP) 2025-022236

(51) Int. Cl. G01R 31/26; G01R 31/265

(52) U.S. Cl. CPC G01R 31/2601; G01R 31/2656

(57) ABSTRACT

The present disclosure is intended to provide a deterioration detection device and a semiconductor device capable of detecting deterioration of a detection object without being affected by a deterioration state of the detection object. A deterioration detection device includes: a first thermoelectric element installed at a first position of a semiconductor module; a second thermoelectric element arranged in the semiconductor module at a second position different from the first position; a light-emitting diode electrically connected to the first thermoelectric element and the second thermoelectric element; a phototransistor detecting light emitted by the light-emitting diode; and a detection circuit detecting deterioration of the semiconductor module based on a light detection value in the phototransistor.

### CROSS REFERENCE TO RELATED APPLICATIONS AND INCORPORATION BY REFERENCE

This application claims benefit of priority under 35 U.S.C. § 119 based on Japanese Patent Application No.2025-022236 filed on February 14, 2025, the entire contents of which are incorporated by reference herein.

### Technical Field

The present disclosure relates to a deterioration detection device and a semiconductor device detecting deterioration of a detection object generating heat in operation.

### Background Art

A semiconductor device is known in which a semiconductor element, which is one of the elements generating heat in operation, is mounted on an insulation wiring board and stored in a single package considering heat dissipation and insulation. In such a semiconductor device, the semiconductor element is mounted on the insulation wiring board by soldering, for example. Materials of the semiconductor element, the insulation wiring board, the solder, and others used in the semiconductor device sometimes differ in expansion rate due to a temperature change. In this case, the heat generated by the operation of the semiconductor element, for example, places physical stress between the materials used in the semiconductor device whenever the temperature change occurs. As a result of the accumulation of the physical stress, cracking or separation sometimes occurs between the materials. This case leads to a change over time in the semiconductor device, and finally leads to breakage of the semiconductor device.

To predict the change over time in the semiconductor device, there are various methods, such as the observation of the temperature change by a temperature sensor. PTL 1 discloses a "power module enabling life estimation at low cost with a simple structure by detecting, at an early stage, a temperature rise of a power semiconductor element due to deterioration or the like of a solder layer only by simple comparison operation".

### Citation List

### Patent Literature

PTL 1: JP 2006-114575 A

### Summary of Invention

### Technical Problem

However, the conventional method has had the problem that the semiconductor element and a detection circuit are electrically connected to each other, which poses a risk that, when the semiconductor element included in a deterioration detection target is broken, the detection circuit is also broken.

It is an object of the present disclosure to provide a deterioration detection device and a semiconductor device capable of detecting deterioration of a detection object without being affected by a deterioration state of the detection object.

### Solution to Problem

To achieve the above-described object, a deterioration detection device according to one aspect of the present disclosure includes: a first thermoelectric element installed at a first position of a detection object; a second thermoelectric element arranged in the detection object at a second position different from the first position; a light-emitting element electrically connected to the first thermoelectric element and the second thermoelectric element; a light detection element detecting light emitted by the light-emitting element; and a detection circuit detecting deterioration of the detection object based on a light detection value in the light detection element.

Further, to achieve the above-described object, a semiconductor device according to one aspect of the present disclosure includes: the deterioration detection device according to the one aspect of the present disclosure described above; and the detection object.

### Advantageous Effects of Invention

The aspects of the present disclosure enable the detection of deterioration of a detection object without being affected by a deterioration state of the detection object.

### BRIEF DESCRIPTION OF DRAWINGS

FIG. 1 is a block diagram illustrating one example of the schematic configuration of a deterioration detection device and a semiconductor device according to one embodiment of the present disclosure;

FIG. 2 is a view explaining the schematic configuration of the semiconductor device and deterioration detection operation in the deterioration detection device according to one embodiment of the present disclosure, and is a cross-sectional view schematically illustrating one example of a state in which no cracking occurs in a solder layer provided in the deterioration detection device and a view illustrating one example of a temperature distribution in the state;

FIG. 3 is a view explaining the deterioration detection operation in the deterioration detection device according to one embodiment of the present disclosure, and is a view illustrating one example of the characteristic of the light emission amount to the voltage of a light-emitting element provided in the deterioration detection device and a forward voltage when no cracking occurs in the solder layer;

FIG. 4 is a view explaining the deterioration detection operation in the deterioration detection device according to one embodiment of the present disclosure, and is a cross-sectional view schematically illustrating one example of a state in which cracking has occurred in the solder layer provided in the deterioration detection device and a view illustrating one example of a temperature distribution in the state;

FIG. 5 is a view explaining the deterioration detection operation in the deterioration detection device according to one embodiment of the present disclosure, and is a plan view schematically illustrating the state in which the cracking has occurred in the solder layer provided in the deterioration detection device (state illustrated in FIG. 4);

FIG. 6 is a view explaining the deterioration detection operation in the deterioration detection device according to one embodiment of the present disclosure, and is view illustrating one example of the characteristic of the light emission amount to the voltage of the light-emitting element provided in the deterioration detection device and a forward voltage when cracking occurs in the solder layer;

FIG. 7 is a view explaining the deterioration detection operation in the deterioration detection device according to one embodiment of the present disclosure, and is a cross-sectional view schematically illustrating one example of a state in which cracking occurring in the solder layer provided in the deterioration detection device has progressed and a view illustrating one example of a temperature distribution in the state;

FIG. 8 is a view explaining the deterioration detection operation in the deterioration detection device according to one embodiment of the present disclosure, and is a plan view schematically illustrating the state in which the cracking occurring in the solder layer provided in the deterioration detection device has progressed (state illustrated in FIG. 7);

FIG. 9 is a perspective view schematically illustrating one example of the appearance of a semiconductor device according to Example 1 of one embodiment of the present disclosure;

FIG. 10 is a perspective view schematically illustrating one example of the internal configuration of a semiconductor module provided in the semiconductor device according to Example 1 of one embodiment of the present disclosure;

FIG. 11 is a side view schematically illustrating a part of the semiconductor module provided in the semiconductor device according to Example 1 of one embodiment of the present disclosure;

FIG. 12 is a perspective view schematically illustrating one example of the appearance of a semiconductor device according to Example 2 of one embodiment of the present disclosure;

FIG. 13 is a perspective view schematically illustrating one example of the internal configuration of a semiconductor module provided in the semiconductor device according to Example 2 of one embodiment of the present disclosure; and

FIG. 14 is a side view schematically illustrating a part of the semiconductor module provided in the semiconductor device according to Example 2 of one embodiment of the present disclosure.

### DESCRIPTION OF EMBODIMENTS

A mode for implementing the present disclosure will now be described with reference to the drawings. In the drawings, the dimension and the scale of each element are sometimes different from the dimension and the scale of actual products. Further, the mode described below is one exemplary mode that is estimated when the present disclosure is implemented. Therefore, the scope of the present disclosure is not limited to the mode exemplified below.

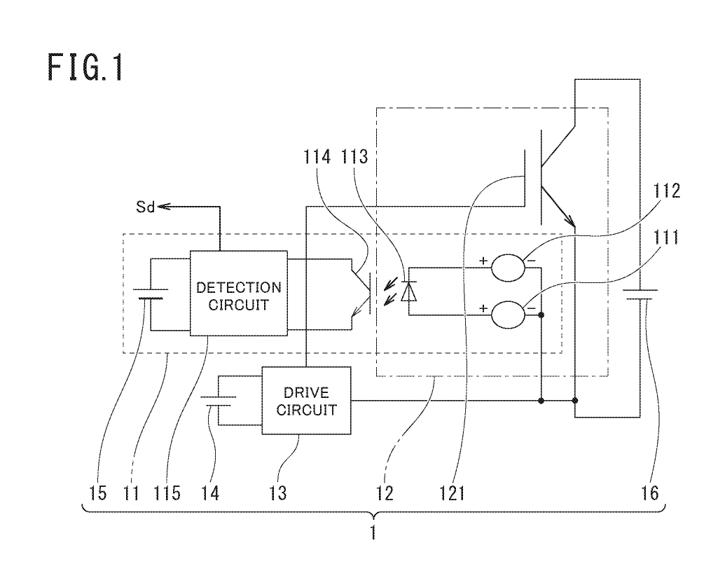

A deterioration detection device and a semiconductor device according to one embodiment of the present disclosure will be described using FIGS. 1 to 14.

1-1. Configuration of deterioration detection device:

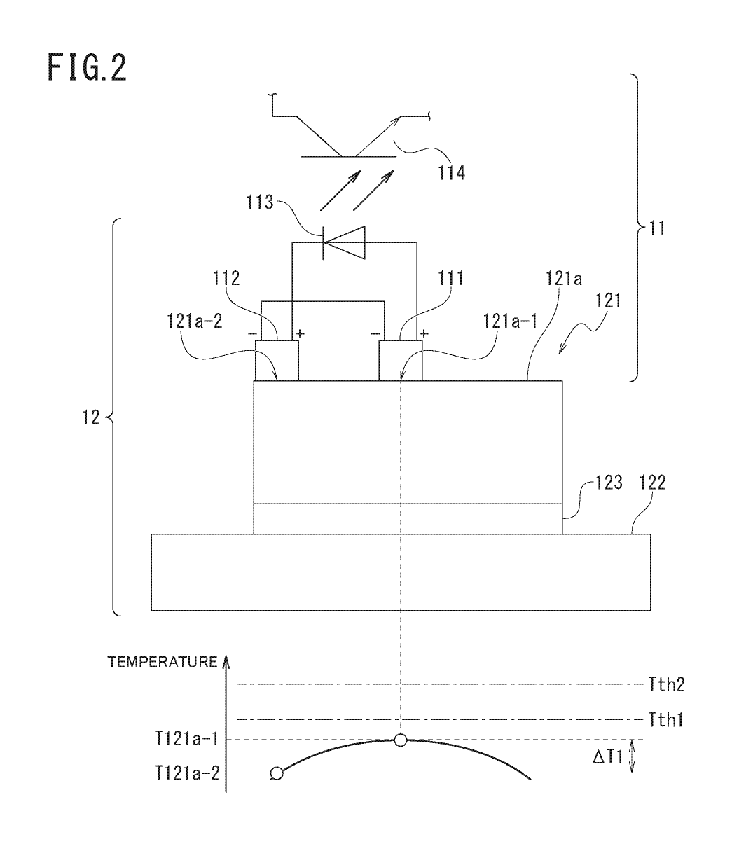

The schematic configuration of a deterioration detection device 11 according to this embodiment will be described using FIGS. 1 and 2. FIG. 1 is a circuit diagram illustrating one example of the schematic configuration of the deterioration detection device 11 and a semiconductor device 1 including the deterioration detection device 11 according to this embodiment.

As illustrated in FIG. 1, the deterioration detection device 11 includes a first thermoelectric element 111 installed at a first position 121a-1 (not illustrated in FIG. 1, see FIG. 2) of an insulated gate bipolar transistor (IGBT) 121 equivalent to one example of the semiconductor element. The deterioration detection device 11 includes a second thermoelectric element 112 arranged in the IGBT 121 at a second position 121a-2 (not illustrated in FIG. 1, see FIG. 2) different from the first position 121a-1.

The deterioration detection device 11 includes a light-emitting diode 113 electrically connected to the first thermoelectric element 111 and the second thermoelectric element 112. The light-emitting diode 113 is equivalent to one example of the light-emitting element. A positive terminal (+) (one example of the output) of the first thermoelectric element 111 is connected to an anode of the light-emitting diode 113. A positive terminal (+) (one example of the output) of the second thermoelectric element 112 is connected to a cathode of the light-emitting diode 113.

The deterioration detection device 11 includes a phototransistor (one example of the light detection element) 114 detecting light emitted by the light-emitting diode 113. The phototransistor 114 is electrically insulated from the light-emitting diode 113. The light-emitting diode 113 and the phototransistor 114 may be separately provided or may be configured by a packaged photocoupler.

The deterioration detection device 11 includes a detection circuit 115 detecting deterioration of the semiconductor module 12 based on a light detection value in the phototransistor 114. The detection circuit 115 is electrically insulated from the semiconductor module 12 (details will be described later) equivalent to one example of the detection object. To the detection circuit 115, a collector and an emitter of the phototransistor 114 are connected. Therefore, the detection circuit 115 detects the current amount of a collector current flowing to the phototransistor 114 according to the received light amount as the light detection value. In the detection circuit 115, a first threshold and a second threshold are set. The second threshold is set to a value higher than the first threshold. The detection circuit 115 notifies the outside that a change over time caused by deterioration occurs in the detection object (the semiconductor module 12 in this embodiment (details will be described later)) when light is detected by the phototransistor 114 and the light detection value is higher than the first threshold and lower than the second threshold. Further, the detection circuit 115 notifies the outside that the detection object has reached the end of its life when the light detection value is higher than the second threshold.

The detection circuit 115 outputs a detection signal Sd to the outside to notify the outside that a change over time occurs in the detection object and the detection object has reached the end of its life. The detection circuit 115 may output different detection signals Sd between a case where the detection circuit 115 has detected the occurrence of the change over time and a case where the detection circuit 115 has detected reaching the end of its life. For example, when the detection circuit 115 has detected the change over time, the detection circuit 115 may output the detection signal Sd blinking the light-emitting element, which is not illustrated. When the detection circuit 115 has detected reaching the end of its life, the detection circuit 115 may output the detection signal Sd lighting the light-emitting element.

The deterioration detection device 11 includes a power supply 15 supplying power to the detection circuit 115. The power supply 15 is configured by a DC power supply, for example.

1-2. Configuration of semiconductor device:

The schematic configuration of the semiconductor device 1 according to this embodiment will be described using FIGS. 1 and 2. The semiconductor device 1 is a device used, for example, in a switching power supply and including semiconductor elements, such as an IGBT and a metal-oxide-semiconductor field-effect transistor (MOSFET).

FIG. 2 is a cross-sectional view schematically illustrating one example of a state in which no cracking occurs in a solder layer 123 provided in the deterioration detection device 11 and a view illustrating one example of a temperature distribution in the state. An upper part in FIG. 2 schematically illustrates a cross-section of a part of the deterioration detection device 11 provided in the semiconductor device 1. A lower part in FIG. 2 illustrates one example of the temperature distribution in a surface 121a of the IGBT 121 on which the first thermoelectric element 111 and the second thermoelectric element 112 are arranged.

As illustrated in FIGS. 1 and 2, the semiconductor device 1 includes a semiconductor module 12 having the IGBT 121, the light-emitting diode 113, an insulation wiring board 122 (not illustrated in FIG. 1) on which the IGBT 121 is arranged, and the solder layer (one example of the adhesive layer) 123 (not illustrated in FIG. 1) having conductivity and bonding the IGBT 121 to the insulation wiring board 122. The semiconductor module 12 is equivalent to one example of the detection object. The solder layer 123 is made of a tin-silver (SnAg) solder, for example. The insulation wiring board 122 is arranged in a state of being thermally connected to a metal plate for heat dissipation (not illustrated) for dissipating heat generated in the IGBT 121.

The IGBT 121 is equivalent to one example of the semiconductor element having the surface 121a (see FIG. 2) on which the first thermoelectric element 111 and the second thermoelectric element 112 are arranged. The semiconductor element is an element generating heat in operation and may be a power MOSFET, for example, without being limited to the IGBT 121.

The first position 121a-1 is a position close to the center of the surface 121a of the IGBT 121. The second position 121a-2 is a position close to the periphery of the surface 121a. The first position 121a-1 is a position closer to the center than the periphery in the surface 121a. The second position 121a-2 is a position closer to the periphery than the center in the surface 121a. Herein, viewing a predetermined plane in a direction orthogonal to the predetermined plane is referred to as "in plan view". The first position 121a-1 is, for example, the center of the surface 121a in plan view of the surface 121a. Therefore, the first thermoelectric element 111 is mounted on a predetermined region including the center of the surface 121a. The second position 121a-2 is a position adjacent to any one of the four end sides of the IGBT 121 in plan view of the surface 121a. The position adjacent to the end side lies, for example, on an imaginary straight line connecting the midpoint in the extension direction of the end side and the center of the surface 121a. The second thermoelectric element 112 is arranged so as not to protrude from the surface 121a at the position adjacent to the end side.

A light-emitting part (not illustrated) of the light-emitting diode 113 and a light-receiving part (not illustrated) of the phototransistor 114 are arranged opposite to each other. This allows the phototransistor 114 to efficiently receive an optical signal output from the light-emitting diode 113.

Returning to FIG. 1, the semiconductor device 1 includes a drive circuit 13 driving the IGBT 121, a power supply 14 (one example of the first power supply) supplying power to the drive circuit 13, a detection circuit 115, and a power supply 15 (one example of the second power supply) electrically insulated from the power supply 14 and supplying power to the detection circuit 115. Further, the semiconductor device 1 includes a power supply 16 electrically insulated from the power supplies 14, 15 and supplying power to the IGBT 121.

An output of the drive circuit 13 is connected to a gate of the IGBT 121. A reference potential part (e.g., ground terminal) maintained at a reference potential of the drive circuit 13 is connected to an emitter of the IGBT 121. To the emitter of the IGBT 121, a negative side of the power supply 16 is connected. To a collector of the IGBT 121, a positive side of the power supply 16 is connected. Thus, the power supply 16 is connected between the collector and the emitter of the IGBT 121. The IGBT 121 performs switching operation by a drive signal output by the drive circuit 13 and input into the gate. The IGBT 121 causes a current input from the power supply 16 in an on state to flow as a collector current to a load device (not illustrated), for example.

To the reference potential part of the drive circuit 13, the emitter of the IGBT 121, and the negative side of the power supply 16, a negative terminal (-) of each of the first thermoelectric element 111 and the second thermoelectric element 112 is connected. A positive terminal (+) of the first thermoelectric element 111 is connected to the cathode of the light-emitting diode 113. A positive side of the second thermoelectric element 112 is connected to the anode of the light-emitting diode 113. Therefore, the first thermoelectric element 111 and the second thermoelectric element 112 are connected to each other by the negative terminals (-). A high power side of electromotive force generated when heat is applied to the first thermoelectric element 111 is the positive terminal (+) of the first thermoelectric element 111, and a low power side of the electromotive force is the negative terminal (-) of the first thermoelectric element 111. Similarly, a high power side of electromotive force generated when heat is applied to the second thermoelectric element 112 is the positive terminal (+) of the second thermoelectric element 112, and a low power side of the electromotive force is the negative terminal (-) of the second thermoelectric element 112.

Thus, the semiconductor device 1 includes the first thermoelectric element 111, the second thermoelectric element 112, the light-emitting diode 113, the phototransistor 114, the detection circuit 115, and the power supply 15 provided in the deterioration detection device 11. Therefore, the semiconductor device 1 includes the deterioration detection device 11 according to this embodiment and the semiconductor module 12 as the detection object.

The semiconductor device 1 includes the power supplies 14, 15, 16 electrically insulated from each other. Specifically, in the power supplies 14, 15, 16, power supply lines (i.e., positive sides) are isolated from each other and electrically insulated from each other. Further, the IGBT 121 and the detection circuit 115 are optically coupled with each other by the light-emitting diode 113 and the phototransistor 114 and are not electrically coupled with each other. This reduces the possibility that deterioration or failure of the semiconductor module 12 caused by heat generation of the IGBT 121, for example, affects the detection circuit 115. This allows the deterioration detection device 11 and the semiconductor device 1 to detect deterioration of the semiconductor module 12 without being affected by a deterioration state of the semiconductor module 12.

1-3. Deterioration detection operation of deterioration detection device:

Deterioration detection operation of the deterioration detection device according to this embodiment will be described using FIGS. 2 to 8 with reference to FIG. 1. The deterioration detection operation of the deterioration detection device will be described taking cracking occurring in the solder layer 123 provided in the semiconductor module 12 as an example of the deterioration in this embodiment.

1-3-1. Case where no deterioration occurs in detection object:

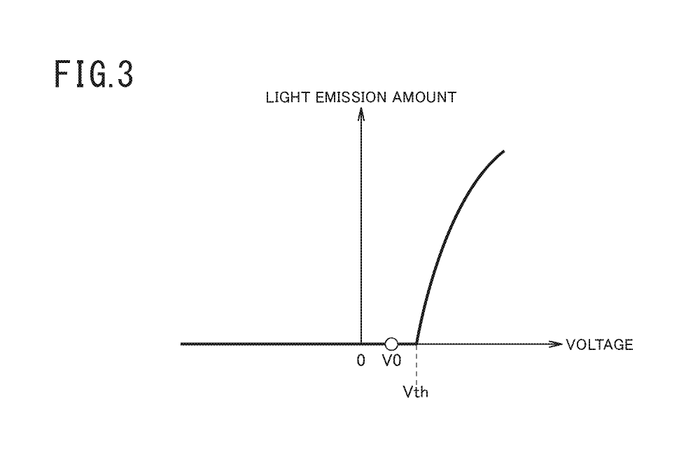

The operation of the deterioration detection device 11 when no deterioration occurs in the semiconductor module 12, which is a deterioration detection object, will be described using FIGS. 2 and 3 with reference to FIG. 1. FIG. 3 is a view illustrating one example of the characteristic of the light emission amount to a forward voltage of the light-emitting diode 113 provided in the deterioration detection device 11. The horizontal axis of a graph illustrated in FIG. 3 represents a forward voltage applied to the light-emitting diode 113, and the vertical axis of the graph represents the light emission amount of the light-emitting diode 113.

The IGBT 121 has a configuration in which the gate and the emitter are arranged on the surface 121a side and the collector is arranged on the rear surface (i.e., surface in contact with the solder layer 123) side of the surface 121a, for example. Therefore, a current input from the power supply 16 when the IGBT 121 is in the on state flows in the thickness direction of the IGBT 121 from the collector to the emitter through the insulation wiring board 122 and the solder layer 123. When the current (i.e., collector current) flows, so that the IGBT 121 operates, the IGBT 121 generates heat. The heat generated in the IGBT 121 is dissipated to the side of the metal plate for heat dissipation (not illustrated) via the solder layer 123 and the insulation wiring board 122.

Even when the heat is dissipated from the metal plate for heat dissipation, the temperature of the IGBT 121 becomes

higher than that in non-operating. When the temperature of the IGBT 121 rises, the surface 121a on which the first thermoelectric element 111 and the second thermoelectric element 112 are arranged has a temperature distribution in which the first position 121a-1 has a temperature higher than that of the second position 121a-2 as illustrated in the lower part in FIG. 2. Thus, the first position 121a-1 is a position where the temperature is higher than that at the second position 121a-2. Therefore, a temperature T121a-1 detected by the first thermoelectric element 111 arranged at the first position 121a-1 becomes higher than a temperature T121a-2 detected by the second thermoelectric element 112 arranged at the second position 121a-2. A difference between the temperature T121a-1 and the temperature T121a-2 detected by the first thermoelectric element 111 and the second thermoelectric element 112, respectively, when no cracking occurs in the solder layer 123 is a temperature difference ΔT1, for example.

The voltage output by the first thermoelectric element 111 becomes higher than the voltage output by the second thermoelectric element 112. The negative terminals (-) of the first thermoelectric element 111 and the second thermoelectric element 112 are connected to each other, and therefore a potential difference between the positive terminals (+) output by the first thermoelectric element 111 and the second thermoelectric element 112 is a voltage applied to the anode and the cathode of the light-emitting diode 113. More specifically, the voltage applied to the anode and the cathode of the light-emitting diode 113 is the voltage corresponding to the temperature difference ΔT1. The potential applied to the anode of the light-emitting diode 113 becomes higher than the potential applied to the cathode of the light-emitting diode 113, and therefore a forward voltage is applied to the light-emitting diode 113.

As illustrated in FIG. 3, the voltage applied to the light-emitting diode 113 corresponding to the temperature difference ΔT1 (see FIG. 2) occurring in the IGBT 121 when no cracking occurs in the solder layer 123 is a forward voltage V1 lower than a threshold voltage Vth of the light-emitting diode 113. Therefore, the light-emitting diode 113 does not emit light (light emission amount is 0), and thus the received light amount in the phototransistor 114 is 0. Therefore, the collector current equivalent to the light detection value does not flow to the phototransistor 114. As a result, the detection circuit 115 (see FIG. 1) does not detect deterioration of the semiconductor module 12, and therefore does not output the detection signal Sd.

It is supposed that the IGBT 121 continues to operate, so that the temperature rises, and the temperature difference ΔT1 between the detected temperatures in the first thermoelectric element 111 and the second thermoelectric element 112 increases, and thus the voltage applied to the light-emitting diode 113 becomes higher than the threshold voltage Vth. In this case, the light-emitting diode 113 emits light, and therefore the collector current flows to the phototransistor 114. The detection circuit 115 does not output the detection signal Sd insofar as the collector current flowing to the phototransistor 114 is lower than the first threshold set in the detection circuit 115.

1-3-2. Case where deterioration occurring in detection object is in initial state:

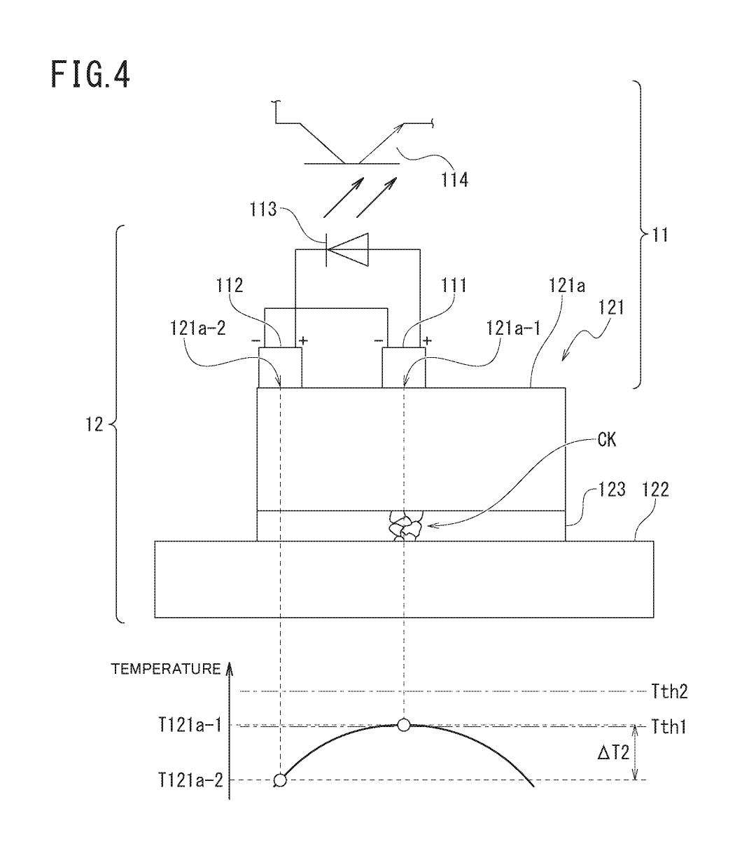

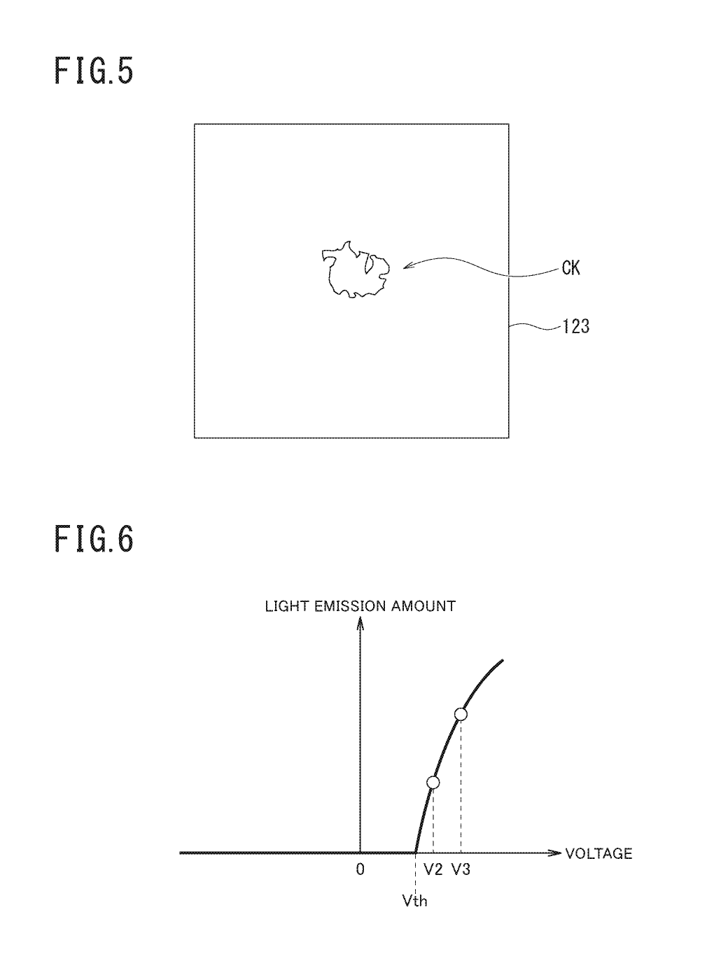

Deterioration detection operation of the deterioration detection device 11 when deterioration occurring in the semiconductor module 12, which is the deterioration detection object, is in an initial state will be described using FIGS. 4 to 6 with reference to FIG. 1. FIG. 4 is a view explaining a state in which cracking CK has occurred in the solder layer 123 provided in the deterioration detection device 11. An upper part in FIG. 4 schematically illustrates a cross-section of the deterioration detection device 11 in the state in which the cracking CK has occurred in the solder layer 123. A lower part in FIG. 4 illustrates one example of a temperature distribution in the surface 121a of the IGBT 121. FIG. 5 is a view schematically illustrating the plane of the solder layer 123 in which the cracking CK in an initial state has occurred. FIG. 6 is a view illustrating one example of the characteristic of the light emission amount to the voltage of the light-emitting diode 113 provided in the deterioration detection device 11. The horizontal axis of a graph illustrated in FIG. 6 represents the voltage applied to the light-emitting diode 113, and the vertical axis of the graph represents the light emission amount of the light-emitting diode 113.

The heat generation or the temperature rise occurring when the IGBT 121 performs switching (i.e., when the on state and an off state are repeated) is repeated, stress generates in the joints of the parts of the semiconductor module 12, particularly in the solder layer 123 between the IGBT 121 and the insulation wiring board 122. The repeated application of the stress to the solder layer 123 sometimes causes the cracking CK in the solder layer 123 as illustrated in the upper part in FIG. 4. The coefficients of thermal expansion of silicon constituting the IGBT 121 and a material (tin or silver in this embodiment) forming the solder layer 123 are different from each other. Therefore, when the temperature of the IGBT 121 rises, the difference in the coefficient of thermal expansion occurs inside as the stress. The cracking CK occurs by the application of the stress generated inside to the solder layer 123.

In a SnAg-based solder, cracking tends to occur in a center part rather than in a peripheral part of a solder layer. Therefore, due to a temperature change (power cycle) caused by the repeated operation and stop of the semiconductor module 12 (the on state and the off state of the IGBT 121), the cracking CK begins to occur in the center part of the solder layer 123 as illustrated in the upper part in FIGS. 4 and FIG. 5. The cracking CK occurring in the solder layer 123 prevents the dissipation of the heat generated in the IGBT 121. Therefore, the heat generated in the IGBT 121 is more difficult to dissipate in the center part than in the

peripheral part of the IGBT 121. Thus, the temperature T121a-1 detected by the first thermoelectric element 111 arranged at the first position 121a-1 becomes higher after the occurrence of the cracking CK than before the occurrence of the cracking CK as illustrated in the lower part in FIG. 4. On the other hand, no cracking occurs in the peripheral part of the IGBT 121. Therefore, the heat dissipation amount in the peripheral part of the IGBT 121 is substantially the same before and after the occurrence of the cracking CK. Thus, the temperature T121a-2 detected by the second thermoelectric element 112 arranged at the second position 121a-2 is substantially the same before and after the occurrence of the cracking CK. As a result, a temperature difference ΔT2 between the temperature T121a-1 and the temperature T121a-2 detected by the first thermoelectric element 111 and the second thermoelectric element 112, respectively, is larger after the occurrence of the cracking CK than before the occurrence of the cracking CK. Thus, a voltage applied to the light-emitting diode 113 corresponding to the temperature difference ΔT2 is a forward voltage V2 higher than the threshold voltage Vth of the light-emitting diode 113 as illustrated in FIG. 5.

The period from the time when the cracking CK begins to occur until a predetermined period of time passes is equivalent to the initial state in which the semiconductor module 12 begins to change over time, for example. In the initial state, the temperature difference ΔT2 between the temperature T121a-1 detected by the first thermoelectric element 111 and the temperature T121a-2 detected by the second thermoelectric element 112 is higher than a threshold temperature Tth1 corresponding to the first threshold set in the detection circuit 115 and lower than a threshold temperature Tth2 corresponding to the second threshold.

By the application of the forward voltage V2, the light-emitting diode 113 emits light, and therefore a collector current flows to the phototransistor 114. The collector current equivalent to the light detection value is larger than the first threshold and smaller than the second threshold. As a result, the detection circuit 115 outputs a detection signal Sd for informing that the change over time occurs in the initial state. When the occurrence of the cracking CK progresses, the temperature of the semiconductor module 12 gradually rises, which sometimes eventually leads to element breakage due to overheating. The deterioration detection device 11 and the semiconductor device 1 including the deterioration detection device 11 can inform the occurrence of the change over time by the detection signal Sd in the initial stage when the change over time of the semiconductor module 12 has occurred, and therefore the failure of the semiconductor module 12 can be prevented.

1-3-3. Case where deterioration occurring in detection object has progressed further than that in initial state:

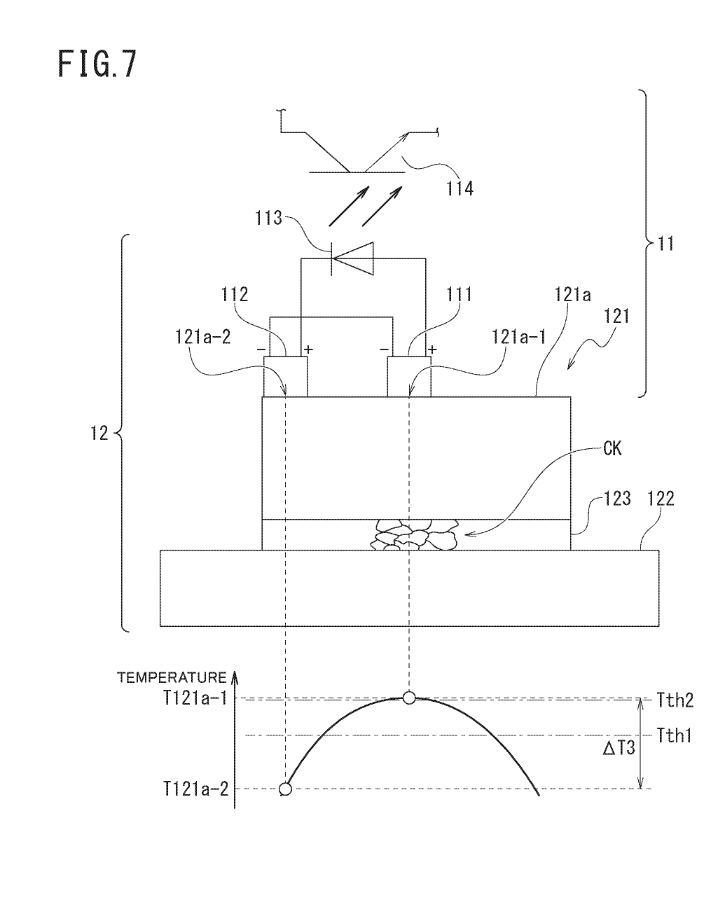

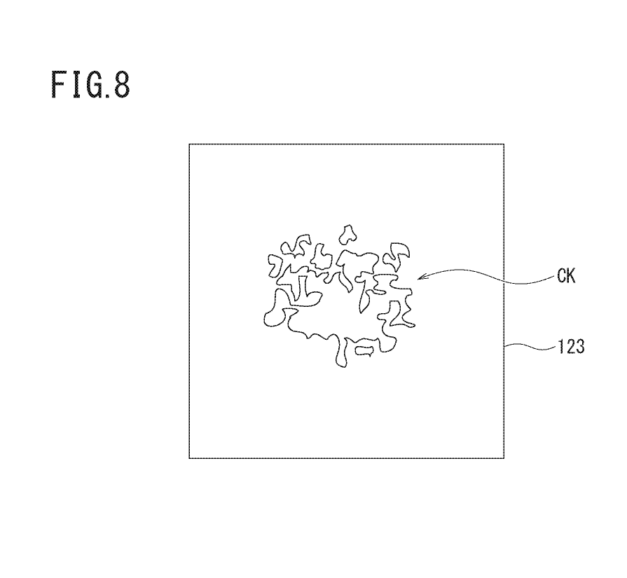

Deterioration detection operation of the deterioration detection device 11 when the deterioration occurring in the semiconductor module 12, which is the deterioration detection object, has progressed further than that in the initial state will be described using FIGS. 7 and 8 with reference to FIGS. 1 and 6. FIG. 7 is a view explaining a case where the cracking CK occurring in the solder layer 123 provided in the deterioration detection device 11 has progressed further than that in the initial state. An upper part in FIG. 7 schematically illustrates a cross-section of the deterioration detection device 11 in the state in which the cracking CK has occurred in the solder layer 123. A lower part in FIG. 7 illustrates one example of the temperature distribution in the surface 121a of the IGBT 121. FIG. 8 is a view schematically illustrating a plane of the solder layer 123 in which the cracking CK has progressed further than that in the initial state.

When the switching operation of the IGBT 121 is continued also during the initial state when the cracking CK has occurred, the range of the cracking CK occurring in the solder layer 123 is widened as illustrated in the upper parts in FIG. 7 and FIG. 8. Therefore, the heat generated in the IGBT 121 is more difficult to dissipate than in the initial state. Thus, as illustrated in the lower part in FIG. 7, the temperature T121a-1 detected by the first thermoelectric element 111 arranged at the first position 121a-1 becomes higher than that in the initial state in which the cracking CK has begun to occur. On the other hand, no cracking occurs in the peripheral part of the IGBT 121. Therefore, the heat dissipation amount in the peripheral part of the IGBT 121 is substantially the same before and after the occurrence of the cracking CK. Thus, the temperature T121a-2 detected by the second thermoelectric element 112 arranged at the second position 121a-2 is substantially the same before and after the occurrence of the cracking CK. As a result, a temperature difference ΔT3 between the temperature T121a-1 detected by the first thermoelectric element 111 and the temperature T121a-2 detected by the second thermoelectric element 112 becomes larger than the temperature difference ΔT2 in the initial state in which the cracking CK has begun to occur. Thus, as illustrated in FIG. 6, the voltage applied to the light-emitting diode 113 corresponding to the temperature difference ΔT3 becomes a forward voltage V3 higher than the threshold voltage Vth and the forward voltage V2 of the light-emitting diode 113.

In the state in which the cracking CK has progressed further than that in the initial state, the temperature difference ΔT3 between the temperature T121a-1 detected by the first thermoelectric element 111 and the temperature T121a-2 detected by the second thermoelectric element 112 becomes higher than the threshold temperature Tth2 corresponding to the second threshold set in the detection circuit 115.

By the application of the forward voltage V3, the light-emitting diode 113 emits light, and therefore a collector current flows to the phototransistor 114. The collector current equivalent to the light detection value is larger than the second threshold. As a result, when the cracking CK has progressed further than the cracking CK in the initial state, the detection circuit 115 outputs the detection signal Sd to inform that the end of its life has been reached. In this embodiment, the time when the semiconductor module 12 reaches the end of its life is set to the time before the semiconductor module 12 fails, for example. Therefore, the deterioration detection device 11 and the semiconductor device 1 including the deterioration detection device 11 can inform that, when the end of its life before the failure of the semiconductor module 12 has been reached, the end of its life has been reached by the detection signal Sd, and therefore the failure of the semiconductor module 12 can be prevented.

1-4. Effects:

The effects of the deterioration detection device and the semiconductor device according to this embodiment will be described.

In PTL 1, a DC constant current source, a life estimation circuit, and the like, which are peripheral circuits, are electrically connected to a semiconductor element which is a main circuit. When the main circuit fails due to a change over time or fails due to factors other than a change over time, there is a possibility that a high current or a high voltage that has been applied to the main circuit is unintentionally applied to the peripheral circuits. The peripheral circuits have lower resistance to both the current and the voltage as compared with the main circuit. Therefore, when the high current or the high voltage is applied to the peripheral circuits, there is a problem that the possibility that the peripheral circuits fail is high. When the peripheral circuits fail together with the main circuit, the main circuit and the peripheral circuits are required to be replaced in restoration.

The power module disclosed in PTL 1 has a problem that complex constituent elements, such as the DC constant current supply and the life estimation circuit, are required, and therefore the manufacturing cost of the power module increases and the selling price of the power module also increases. Therefore, the application of the power module disclosed in PTL 1 is limited to some products in a high-price range, and the application of the power module to products in a popular price range is difficult.

In contrast thereto, the deterioration detection device 11 according to this embodiment includes the power supply 15 electrically insulated from the power supply 16 for the IGBT 121 equivalent to the main circuit and the power supply 14 for the drive circuit 13 driving the IGBT 121. Further, in the deterioration detection device 11, the first thermoelectric element 111 and the second thermoelectric element 112 detecting the temperature of the IGBT 121 are optically coupled with and electrically insulated from the detection circuit 115 detecting deterioration of the semiconductor module 12 having the IGBT 121. This allows the deterioration detection device 11 and the semiconductor device 1 including the deterioration detection device 11 to detect deterioration of the semiconductor module 12 without being affected by a change over time or failure of the semiconductor module 12 having the IGBT 121.

The deterioration detection device 11 can also detect deterioration of the semiconductor module 12 based on the voltage according to a temperature difference between the first thermoelectric element 111 and the second thermoelectric element 112 arranged on the surface 121a of the IGBT 121. This allows the deterioration detection device 11 and the semiconductor device 1 to be mounted with a detection function and a notification function for the change over time or the reaching the end of its life of the semiconductor module 12 without being provided with the DC constant current source or the life estimation circuit.

Thus, the deterioration detection device 11 and the semiconductor device 1 can detect deterioration of the semiconductor module 12 without being affected by a deterioration state of the semiconductor module 12. Further, the deterioration detection device 11 and the semiconductor device 1 can achieve a cost reduction by reducing the manufacturing cost.

1-5. Example 1:

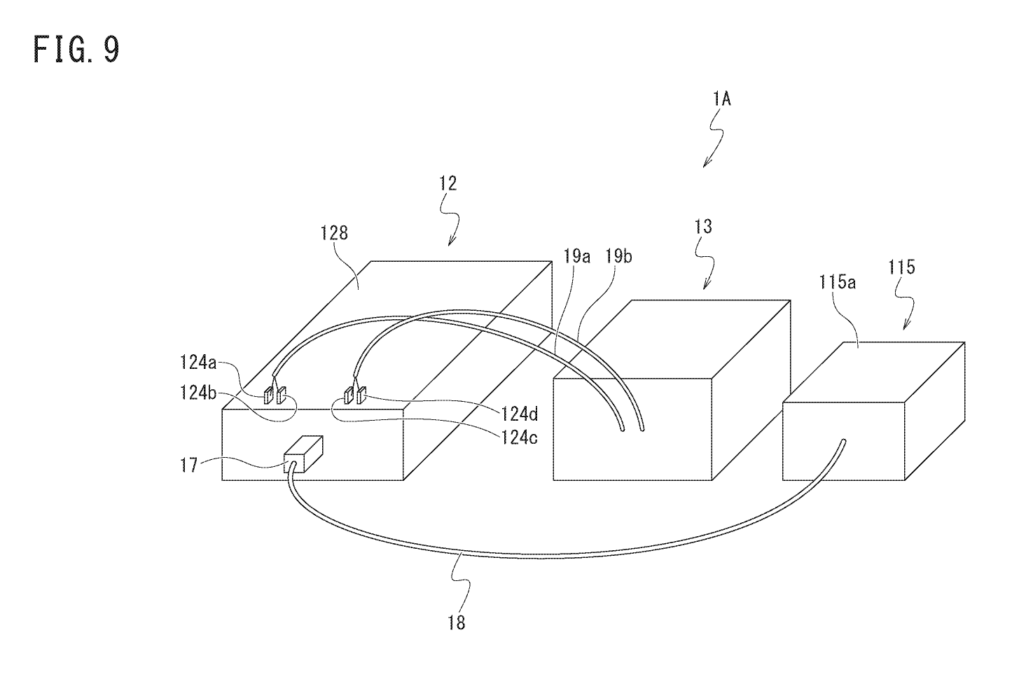

A deterioration detection device and a semiconductor device according to Example 1 of this embodiment will be described using FIGS. 9 to 11 with reference to FIGS. 1 and 2. The deterioration detection device and the semiconductor device according to this example have the same circuit configurations as those of the deterioration detection device 11 and the semiconductor device 1, respectively, illustrated in FIG. 1. In the description of the deterioration detection device and the semiconductor device according to this example, constituent elements exhibiting the same actions and functions as those of the deterioration detection device 11 and the semiconductor device 1, respectively, according to this embodiment described above are attached with the same reference signs, and descriptions thereof are omitted.

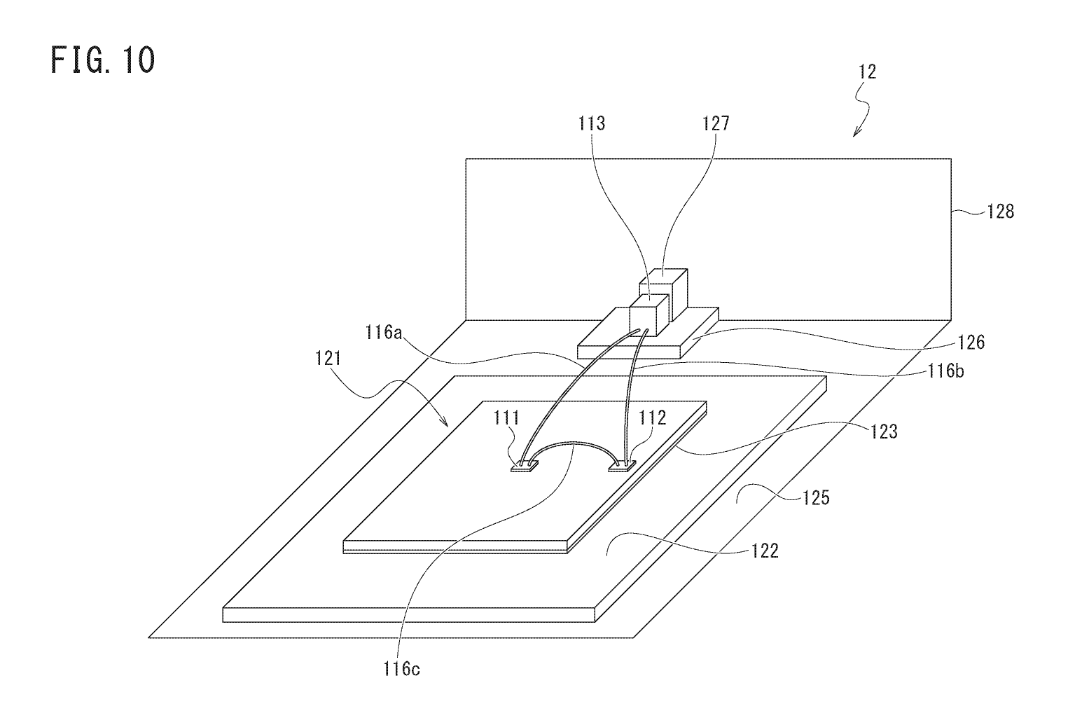

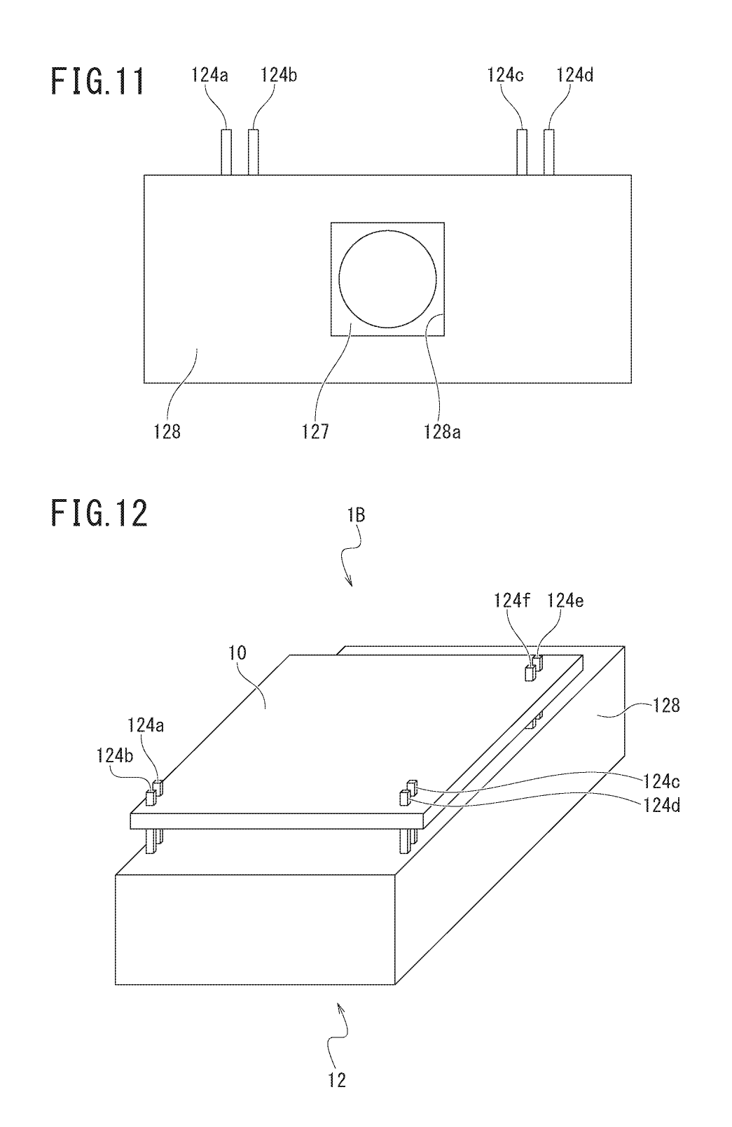

FIG. 9 is a perspective view schematically illustrating one example of the appearance of a semiconductor device 1A according to this example. FIG. 10 is a perspective view schematically illustrating one example of a principal part of the internal configuration of the semiconductor module 12 provided in the semiconductor device 1A according to this example. For ease of understanding, FIG. 10 does not illustrate the upper surface and three side surfaces of an exterior 128 provided in the semiconductor module 12. FIG. 11 is a side view schematically illustrating a part of the semiconductor module 12 provided in the semiconductor device 1A according to this example.

As illustrated in FIG. 9, the semiconductor device 1A according to this example includes the semiconductor module 12, the drive circuit 13, and the detection circuit 115. The semiconductor module 12 is provided independently of the drive circuit 13 and the detection circuit 115. The drive circuit 13 and the detection circuit 115 are provided independently of each other.

The semiconductor device 1A includes an optical fiber 18 provided with a connector 17 at one end. The semiconductor module 12 and the detection circuit 115 are connected to each other by the optical fiber 18.

The semiconductor module 12 includes the exterior 128 having the IGBT 121 (see FIG. 1) and the like inside. The semiconductor module 12 includes control terminals 124a, 124b each having one end electrically connected to the gate of the IGBT 121 and the other end arranged to be exposed to the outside from the exterior 128, for example. The semiconductor module 12 includes control terminals 124c, 124d each having one end electrically connected to the emitter of the IGBT 121 and the other end arranged to be exposed to the outside from the exterior 128, for example.

The semiconductor module 12 and the drive circuit 13 are connected to each other by control wiring lines 19a, 19b. One end of the control wiring line 19a is connected to the other ends of the control terminals 124a, 124b. The other end of the control wiring line 19a is connected to the drive circuit 13. One end of the control wiring line 19b is connected to the other ends of the control terminals 124c, 124d. The other end of the control wiring line 19b is connected to the drive circuit 13.

As illustrated in FIG. 10, the semiconductor module 12 includes a metal plate for heat dissipation 125 arranged in a bottom part. The exterior 128 is arranged surrounding the metal plate for heat dissipation 125. The exterior 128 and the metal plate for heat dissipation 125 form a predetermined internal space. The semiconductor module 12 includes the insulation wiring board 122 and an insulation wiring board 126 fastened to the metal plate for heat dissipation 125 in the internal space. The insulation wiring boards 122, 126 are thermally connected to the metal plate for heat dissipation 125.

On the insulation wiring board 122, the IGBT 121 fastened to the insulation wiring board 122 by the solder layer 123 is arranged. The IGBT 121 is thermally connected to the insulation wiring board 122. At the first position 121a-1 (see FIG. 2) of the surface 121a of the IGBT 121, the first thermoelectric element 111 is arranged. At the second position 121a-2 (see FIG. 2) of the surface 121a of the IGBT 121, the second thermoelectric element 112 is arranged.

Onto the insulation wiring board 126, the light-emitting diode 113 and an adapter 127 are fixed. The anode of the light-emitting diode 113 is connected to the positive terminal (+) (see FIG. 2) of the first thermoelectric element 111 by a wiring line wire 116a. The cathode of the light-emitting diode 113 is connected to the positive terminal (+) (see FIG. 2) of the second thermoelectric element 112 by a wiring line wire 116b. The negative terminal (-) (see FIG. 2) of the first thermoelectric element 111 and the negative terminal (-) (see FIG. 2) of the second thermoelectric element 112 are connected to each other by a wiring line wire 116c.

As illustrated in FIG. 11, an opening part 128a is formed in a part of the side surface of the exterior 128. The adapter 127 is arranged to be exposed to the opening part 128a. The connector 17 (not illustrated in FIG. 11, see FIG. 9) is connected in an optically coupled state to the adapter 127 exposed to the opening part 128a. The other end of the optical fiber 18 (not illustrated in FIG. 11, see FIG. 9) is connected, in a state of being optically coupled with the phototransistor 114 (not illustrated in FIGS. 9 to 11, see FIG. 1) provided in the exterior 115a of the detection circuit 115, to an exterior 115a. Thus, the light-emitting diode 113 and the phototransistor 114 are optically coupled with each other via the adapter 127, the connector 17, and the optical fiber 18.

The semiconductor device 1A according to this example has the first thermoelectric element 111, the second thermoelectric element 112, and the light-emitting diode 113 arranged in the exterior 128 of the semiconductor module 12, the detection circuit 115, and the phototransistor 114 arranged in the exterior 115a of the detection circuit 115, and therefore includes the deterioration detection device 11.

Therefore, the deterioration detection device 11 and the semiconductor device 1A according to this example obtain the same effects as those of the deterioration detection device 11 and the semiconductor device 1, respectively, according to this embodiment.

1-6. Example 2:

A deterioration detection device and a semiconductor device according to Example 2 of this embodiment will be described using FIGS. 12 to 14 with reference to FIG. 1. The deterioration detection device and the semiconductor device according to this example have the same circuit configurations as those of the deterioration detection device 11 and the semiconductor device 1, respectively, illustrated in FIG. 1. In the description of the deterioration detection device and the semiconductor device according to this example, constituent elements exhibiting the same actions and functions as those of the deterioration detection device 11 and the semiconductor devices 1, 1A, respectively, according to this embodiment described above or Example 1 described above are attached with the same reference signs, and descriptions thereof are omitted.

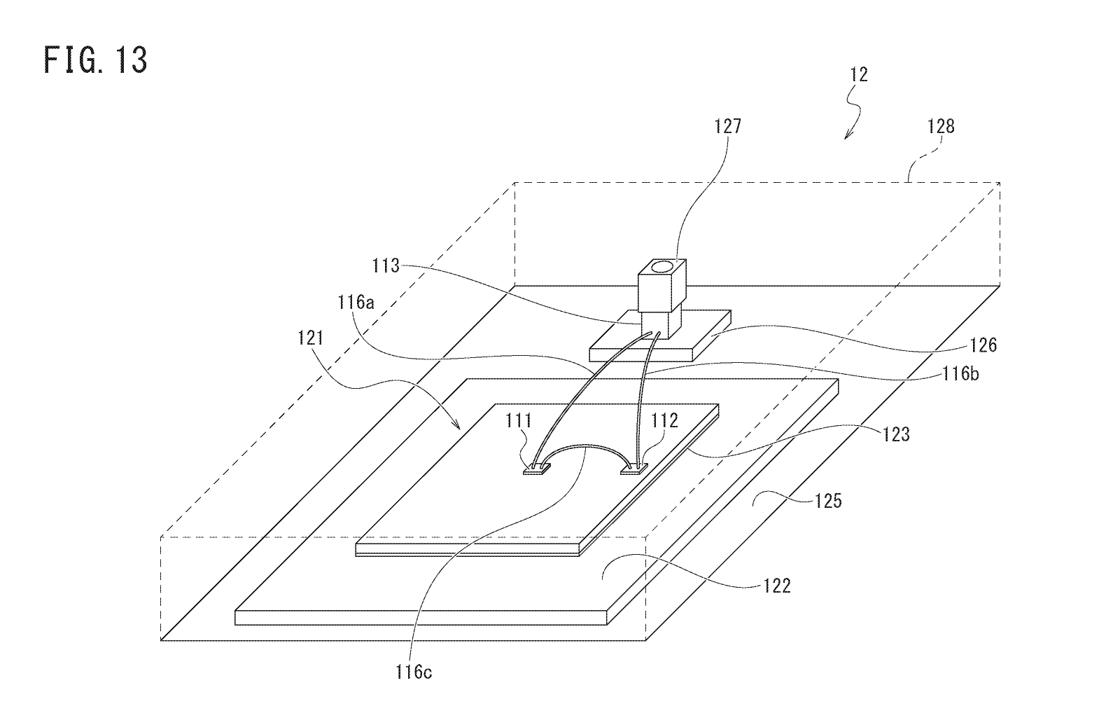

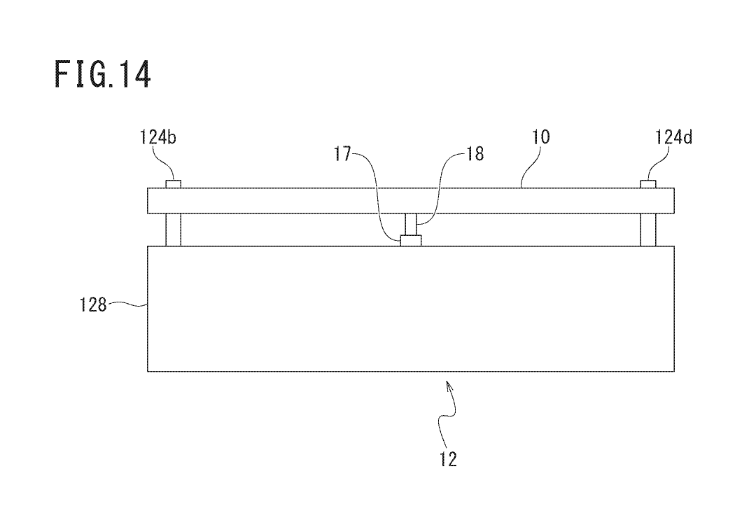

FIG. 12 is a perspective view schematically illustrating one example of the appearance of a semiconductor device 1B according to this example. FIG. 13 is a perspective view schematically illustrating one example of a principal part of the internal configuration of the semiconductor module 12 provided in the semiconductor device 1B according to this example. For ease of understanding, FIG. 13 illustrates the exterior 128 provided in the semiconductor module 12 with dashed lines and in a transparent manner. FIG. 14 is a side view schematically illustrating a part of the semiconductor module 12 provided in the semiconductor device 1B according to this example.

As illustrated in FIG. 12, the semiconductor device 1B according to this example includes the semiconductor module 12 and a mixed circuit 10 having the drive circuit 13 and the detection circuit 115 (not illustrated in FIG. 12, see FIG. 1). The semiconductor module 12 is provided independently of the mixed circuit 10. Although not illustrated, the power supply 14 (see FIG. 1) supplying power to the drive circuit 13 and the power supply 15 (see FIG. 1) supplying power to the detection circuit 115 provided in the mixed circuit 10 are provided in the mixed circuit 10 in an electrically insulated manner. Therefore, the drive circuit 13 and the detection circuit 115 provided in the semiconductor device 1B are electrically insulated from each other.

The semiconductor module 12 and the mixed circuit 10 are connected to each other by the control terminals 124a, 124b, the control terminals 124c, 124d, and control terminals 124e, 124f projecting outward from the exterior 128. Although not illustrated, the control terminals 124a, 124b, 124c, 124d are electrically connected to the drive circuit 13 provided in the mixed circuit 10.

As illustrated in FIG. 12, the semiconductor module 12 in this example has the same internal configuration as that of the semiconductor module 12 in Example 1 described above, except that the arrangement of the adapter 127 is different.

In the semiconductor module 12 in this example, the adapter 127 is arranged on the light-emitting diode 113. The adapter 127 is arranged to be exposed to an opening part (not illustrated) formed in the upper surface of the exterior 128.

As illustrated in FIGS. 13 and 14, the connector 17 (not illustrated in FIG. 13) provided at one end of the optical fiber 18 (not illustrated in FIG. 13) is connected in an optically coupled state to the adapter 127 (not illustrated in FIG. 14) exposed to the upper surface of the exterior 128. The other end of the optical fiber 18 is connected, in a state of being optically coupled with the phototransistor 114 (not illustrated in FIGS. 13 and 14, see FIG. 1) provided in the mixed circuit 10, to the mixed circuit 10. Thus, the light-emitting diode 113 and the phototransistor 114 are optically coupled with each other via the adapter 127, the connector 17, and the optical fiber 18.

The semiconductor device 1B according to this example has the first thermoelectric element 111, the second thermoelectric element 112, and the light-emitting diode 113 arranged in the exterior 128 of the semiconductor module 12 and the detection circuit 115 and the phototransistor 114 arranged in the mixed circuit 10, and therefore includes the deterioration detection device 11.

Therefore, the deterioration detection device 11 and the semiconductor device 1B according to this example obtain the same effects as those of the deterioration detection device 11 and the semiconductor device 1, respectively, according to this embodiment.

As described above, the deterioration detection device 11 according to this embodiment includes the first thermoelectric element 111 installed at the first position 121a-1 of the semiconductor module 12, the second thermoelectric element 112 arranged in the semiconductor module 12 at the second position 121a-2 different from the first position 121a-1, the light-emitting diode 113 electrically connected to the first thermoelectric element 111 and the second thermoelectric element 112, the phototransistor 114 detecting light emitted by the light-emitting diode 113, and the detection circuit 115 detecting deterioration of the semiconductor module 12 based on the light detection value in the phototransistor 114.

The semiconductor device 1 according to this embodiment includes the deterioration detection device 11 according to this embodiment and the semiconductor module 12.

The deterioration detection device 11 and the semiconductor device 1 having such configurations can detect deterioration of the semiconductor module 12 without being affected by a deterioration state of the semiconductor module 12.

The present disclosure can be variously modified without being limited to the embodiment described above.

Although the embodiment described above gives the description taking the semiconductor module 12 as an example of the deterioration detection object, the present disclosure is not limited thereto. For example, the deterioration detection object may be an element, an instrument, or a device having a plurality of places having temperature differences depending on the operation.

Although the embodiment described above gives the description taking the light-emitting diode as an example of the light-emitting element and taking the phototransistor as an example of the light detection element, the present disclosure is not limited thereto. For example, the light-emitting element may be a semiconductor laser, and the light detection element may be a photodiode.

Although, in the embodiment described above, the first threshold and the second threshold set in the detection circuit 115 are used to inform the occurrence of a change over time and the reaching the end of its life, the present disclosure is not limited thereto. For example, it may be acceptable that a plurality of light-emitting elements having threshold voltages different from each other is provided, and a combination of lighting manners of the plurality of light-emitting elements is used to inform the occurrence of a change over time and the reaching the end of its life.

### REFERENCE SIGNS LIST

1, 1A, 1B: semiconductor device

10: mixed circuit

11: deterioration detection device

12: semiconductor module

13: drive circuit

14, 15, 16: power supply

17: connector

18: optical fiber

19a, 19b: control wiring line

111: first thermoelectric element

112: second thermoelectric element

113: light-emitting diode

114: phototransistor

115: detection circuit

115a, 128: exterior

116a, 116b, 116c: wiring line wire

121: IGBT

121a: surface

121a-1: first position

121a-2: second position

122, 126: insulation wiring board

123: solder layer

124a, 124b, 124c, 124d, 124e, 124f: control terminal

125: metal plate for heat dissipation

127: adapter

128a: opening part

CK: cracking

Sd: detection signal

1. A deterioration detection device comprising:
a first thermoelectric element installed at a first position of a detection object;
a second thermoelectric element arranged in the detection object at a second position different from the first position;
a light-emitting element electrically connected to the first thermoelectric element and the second thermoelectric element;
a light detection element configured to detect light emitted by the light-emitting element; and
a detection circuit configured to detect deterioration of the detection object based on a light detection value in the light detection element.

2. The deterioration detection device according to claim 1, wherein the first position is a position where a temperature is higher than a temperature at the second position.

3. The deterioration detection device according to claim 2, wherein
the light-emitting element is a light-emitting diode,
an output of the first thermoelectric element is connected to a cathode of the light-emitting diode, and
an output of the second thermoelectric element is connected to an anode of the light-emitting diode.

4. The deterioration detection device according to claim 1, wherein
a first threshold and a second threshold are set in the detection circuit,
the detection circuit is configured to:
notify an outside that a change over time caused by deterioration occurs in the detection object when the light is detected by the light detection element and the light detection value is higher than the first threshold and lower than the second threshold; and
notify the outside that the detection object has reached an end of a life of the detection object when the light detection value is higher than the second threshold.

5. A semiconductor device comprising:
the deterioration detection device according to claim 1; and
the detection object.

6. The semiconductor device according to claim 5, wherein
the detection object includes a semiconductor element in which the first thermoelectric element and the second thermoelectric element are arranged,
the first position is a position close to a center of a surface of the semiconductor element, and
the second position is a position close to a periphery of the surface of the semiconductor element.

7. The semiconductor device according to claim 6 comprising:
a semiconductor module having the semiconductor element, the light-emitting element, an insulation wiring board on which the semiconductor element is arranged, and an adhesive layer having conductivity and configured to bond the semiconductor element to the insulation wiring board;
a drive circuit configured to drive the semiconductor element;
a first power supply configured to supply power to the drive circuit;
the detection circuit; and
a second power supply electrically insulated from the first power supply and configured to supply power to the detection circuit, wherein
the detection object is the semiconductor module.

8. The semiconductor device according to claim 7, wherein the drive circuit and the detection circuit are provided independently of each other.

9. The semiconductor device according to claim 7, comprising:
a mixed circuit having the drive circuit and the detection circuit.

10. A semiconductor device comprising:
the deterioration detection device according to claim 2; and
the detection object.

11. A semiconductor device comprising:
the deterioration detection device according to claim 3; and
the detection object.

12. A semiconductor device comprising:
the deterioration detection device according to claim 4; and
the detection object.

13. The semiconductor device according to claim 10, wherein
the detection object includes a semiconductor element in which the first thermoelectric element and the second thermoelectric element are arranged,
the first position is a position close to a center of a surface of the semiconductor element, and
the second position is a position close to a periphery of the surface of the semiconductor element.

14. The semiconductor device according to claim 11, wherein
the detection object includes a semiconductor element in which the first thermoelectric element and the second thermoelectric element are arranged,
the first position is a position close to a center of a surface of the semiconductor element, and
the second position is a position close to a periphery of the surface of the semiconductor element.

15. The semiconductor device according to claim 12, wherein
the detection object includes a semiconductor element in which the first thermoelectric element and the second thermoelectric element are arranged,
the first position is a position close to a center of a surface of the semiconductor element, and
the second position is a position close to a periphery of the surface of the semiconductor element.

16. The semiconductor device according to claim 10 comprising:
a semiconductor module having the semiconductor element, the light-emitting element, an insulation wiring board on which the semiconductor element is arranged, and an adhesive layer having conductivity and configured to bond the semiconductor element to the insulation wiring board;
a drive circuit configured to drive the semiconductor element;
a first power supply configured to supply power to the drive circuit;
the detection circuit; and
a second power supply electrically insulated from the first power supply and configured to supply power to the detection circuit, wherein
the detection object is the semiconductor module.

17. The semiconductor device according to claim 11 comprising:
a semiconductor module having the semiconductor element, the light-emitting element, an insulation wiring board on which the semiconductor element is arranged, and an adhesive layer having conductivity and configured to bond the semiconductor element to the insulation wiring board;
a drive circuit configured to drive the semiconductor element;
a first power supply configured to supply power to the drive circuit;
the detection circuit; and
a second power supply electrically insulated from the first power supply and configured to supply power to the detection circuit, wherein
the detection object is the semiconductor module.

18. The semiconductor device according to claim 12 comprising:
a semiconductor module having the semiconductor element, the light-emitting element, an insulation wiring board on which the semiconductor element is arranged, and an adhesive layer having conductivity and configured to bond the semiconductor element to the insulation wiring board;
a drive circuit configured to drive the semiconductor element;
a first power supply configured to supply power to the drive circuit;
the detection circuit; and
a second power supply electrically insulated from the first power supply and configured to supply power to the detection circuit, wherein
the detection object is the semiconductor module.

19. The semiconductor device according to claim 10, wherein the drive circuit and the detection circuit are provided independently of each other.

20. The semiconductor device according to claim 11, wherein the drive circuit and the detection circuit are provided independently of each other.
